(19) United States
(12) Patent Application Publication
(10) Pub. No.: US 2009/0140602 A1
(43) Pub. Date: Jun. 4, 2009

(54) METHOD AND SYSTEM FOR MITIGATING AN UNINTENDED-MECHANICAL STRAIN

(75) Inventors: MARTIN R. PAIS, NORTH BARRINGTON, IL (US); SHUMIN CHENG, VERNON HILLS, IL (US); MICHAEL D KOTZIN, BUFFALO GROVE, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/949,381

(22) Filed: Dec. 3, 2007

(51) Int. Cl. F16F 15/03; H01L 41/113; H02N 2/00

(52) U.S. Cl. 310/300; 310/319

(57) ABSTRACT

The present invention provides a method for mitigating an unintended-mechanical strain in a device (100). The method includes transducing (304) strain-energy in the device to electrical-potential energy. This strain-energy develops due to unintended-mechanical strain. The unintended-mechanical strain is generated due to an impact force received by the device. Further, the method includes dissipating (306) the electrical-potential energy. The electrical-potential energy is dissipated via an electrical-circuit (204) in the device.

### FIELD OF THE INVENTION

The present invention relates generally to the field of mechanical strain and more specifically, to mitigating unintended-mechanical strain in a device.

### BACKGROUND OF THE INVENTION

Advancements in technology have provided many devices to aid our fast-paced lives in today's world. These devices can be small or big, bulky or portable, robust or sensitive. Examples of these devices and can include mobile phones, radios, pagers, alarm clocks, laptop computers and personal digital assistants (PDAs). Such devices are required to hold considerable amounts of information and a large number of functionalities, and yet be portable. To fulfill these requirements, these devices, and more specifically electronic devices, pack a large number of components within a limited space. This high density of components makes the devices very sensitive and therefore susceptible to even small relative movements of the components. A relative movement of the components can occur when these devices come into contact with hard surfaces while traveling at a relatively high speed, regardless as to whether the device is currently performing any of its intended functions. This contact can often be in the form of vibrations or impacts. A contact in the form of vibrations can result, for example, when the device is kept on a vibrating surface, if the device moves with respect to a stationary surface, or when the internal operations of the device cause it to vibrate. Moreover, a contact in the form of an impact can occur when, for example, the device falls under gravity and hits the floor, a moving device travels into a wall, the device is struck by an object, or when the device undergoes any combination of the aforementioned types of impacts.

The contact of the device with a hard surface can result in conversion of the kinetic energy of the relative movement of the device and the hard surface into mechanical energy. Normally, a part of this mechanical energy is instantaneously transferred to the hard surface, another part is transferred to the device, and the rest is lost by dissipation as sound-energy, heat-energy and/or light-energy. The part of the mechanical energy transferred to the hard surface is absorbed in bending, depression, fracture or abrasion of the hard surface. The part of the mechanical energy that is transferred to the device is usually dissipated through bending, fracture and friction at the device and its respective components. This can induce an unintended-mechanical strain in the device, which can cause breakage and/or physical damage to the device and its various components. Often, such unintended-mechanical strain can also result in the relative displacement of the components of the device, which can negatively affect its normal operation. Therefore, these devices can sometimes become sensitive to even a small amount of unintended-mechanical strain.

Attempts have been made earlier to develop systems and methods for mitigating the unintended-mechanical strain in the devices. Typically, these existing systems and methods have one or more of the following limitations. First, some of these existing systems and methods are equipped to dampen and weaken very specific forms of known or expected vibrations, where the source and the direction of the vibrations are relatively uniform and well defined. For example, shock absorbing materials can be used proximate the mounting of a motor to a housing. However, not all mechanical strain inducing contacts are from an expected source or are from an expected direction. Therefore, these existing systems and methods are often unable to address the unintended-mechanical strain caused by the impacts. Secondly, the existing systems and methods provide active systems for damping the vibrations. However, these active systems require a feedback mechanism that relies on a transducer to sense the unintended-mechanical strain and help to provide mechanical stresses to induce a counter-mechanical strain.

### SUMMARY OF THE INVENTION

The present invention provides a method and a system for mitigating an unintended-mechanical strain in a device. This unintended-mechanical strain can develop due to an impact force received by the device. For example, the device can experience the impact force on striking a hard surface at a relatively high speed. The unintended-mechanical strain generated in the device due to the impact force can cause damage to its components.

In at least one embodiment of the present invention, the method for mitigating an unintended-mechanical strain includes transducing strain-energy to electrical-potential energy. The strain-energy develops in the device due to the unintended-mechanical strain. The unintended-mechanical strain is generated due to an impact force received by the device. Further, the method includes dissipating the electrical-potential energy via an energy dissipating electrical-circuit on the device.

In another embodiment of the present invention, a device for mitigating an unintended-mechanical strain is provided. The device includes a transducer and an energy dissipating electrical-circuit. The transducer is capable of converting strain-energy to electrical-potential energy. The strain-energy is developed in the device due to the unintended-mechanical strain. The unintended-mechanical strain can be generated in the device due to an impact force received by the device. Further, the device includes an electric circuit capable of dissipating the electrical-potential energy via the electrical-circuit.

These and other features, as well as the advantages of this invention, are evident from the following description of one or more embodiments of this invention, with reference to the accompanying figures.

### BRIEF DESCRIPTION OF THE FIGURES

The accompanying figures, where like reference numerals refer to identical or functionally similar elements throughout the separate views, and which, together with the detailed description below, are incorporated in and form part of the specification, serve to further illustrate various embodiments and explain various principles and advantages, all in accordance with the present invention.

FIG. 1 illustrates a device that can experience an unintended-mechanical strain due to an impact force, where various embodiments of the present invention can be applicable;

FIG. 2 illustrates a device that can mitigate an unintended-mechanical strain experienced by the device, in accordance with at least one embodiment of the present invention;

FIG. 3 is a flow diagram illustrating a method for mitigating an unintended-mechanical strain in a device, in accordance with at least one embodiment of the present invention; and

FIG. 4 is a flow diagram illustrating a method for mitigating an unintended-mechanical strain, in accordance with yet another embodiment of the present invention.

Skilled artisans will appreciate that the elements in the figures are illustrated for simplicity and clarity and have not necessarily been drawn to scale. For example, the dimensions of some of the elements in the figures may be exaggerated, relative to the other elements, to help in improving understanding of the embodiments of the present invention.

### DETAILED DESCRIPTION

Before describing in detail the particular method and system for mitigating an unintended-mechanical strain, in accordance with various embodiments of the present invention, it should be observed that the present invention resides primarily in combinations of method steps and apparatus components related to the method and system for mitigating an unintended-mechanical strain. Accordingly, the apparatus components and method steps have been represented, where appropriate, by conventional symbols in the drawings, showing only those specific details that are pertinent for an understanding of the present invention, so as not to obscure the disclosure with details that will be readily apparent to those with ordinary skill in the art, having the benefit of the description herein.

In this document, the terms ‘comprises,’ ‘comprising,’ ‘includes,’ or any other variation thereof, are intended to cover a non-exclusive inclusion, such that an article or apparatus that comprises a list of elements does not include only those elements, but may include other elements that are not expressly listed or inherent in such an article or apparatus. An element proceeded by ‘comprises . . . a’ does not, without more constraints, preclude the existence of additional identical elements in the article or apparatus that comprises the element. The term ‘another,’ as used in this document, is defined as at least a second or more. The terms ‘includes’ and/or ‘having’, as used herein, are defined as comprising.

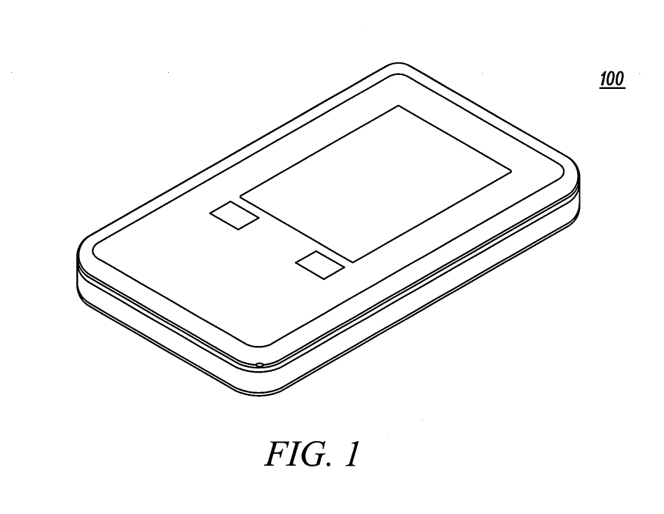

FIG. 1 illustrates a device 100 that can experience an unintended-mechanical strain due to an impact force, where various embodiments of the present invention can be applicable. Examples of the device 100 can include, but are not limited to, a mobile-phone, a radio phone, a pager, a laptop, a palmtop, a music playback device (an MP3 player), a Digital Video Drive (DVD), a Read Only Memory (ROM) and a Personal Digital Assistant (PDA). In at least one embodiment, the device 100 can be a wireless-communication device and can include various components. Exemplary components include, but are not limited to, a housing, a keyboard, a Liquid Crystal Display (LCD) and a Printed Circuit Board (PCB). The components can be made of a combination of materials that can include glass, a plastic resin, a fiber polymer, rubber, a metallic alloy and a semi-conductor material. These components have a threshold level of resistance against mechanical strain and can bend and fracture when the unintended-mechanical strain exceeds the threshold level. The unintended-mechanical strain can develop in the device 100 due to an impact force received by the device. This impact force can occur when the device 100 strikes and/or comes into contact with a surface with a relative speed. Examples of the surface can include, but are not limited to, a floor surface, the surface of a hard-bound book, the surface of a table, and the surface of a wall. A relative motion occurs, when one of the device 100 or the surface is stationary, and the other one is in motion. The relative motion can also occur when there is a difference in the speeds of the device 100 and the surface. Examples of such relative motions include the device 100 falling under gravity and an object striking the device 100.

In at least one embodiment, the kinetic energy of the device 100 upon impact of the device with another object or surface is converted to internal energy of the device 100, such as heat-energy and/or sound-energy. The internal energy can induce the unintended-mechanical strain in one or more components of the device 100. This unintended-mechanical strain can cause the one or more components to bend, flex and/or fracture. Further, the impact force can cause friction between the different components of the device 100, resulting in wear and tear. For example, a mobile-phone can dissipate about 1.8 Watts of energy, during a two feet drop, through bending, fracture and/or friction within its different components.

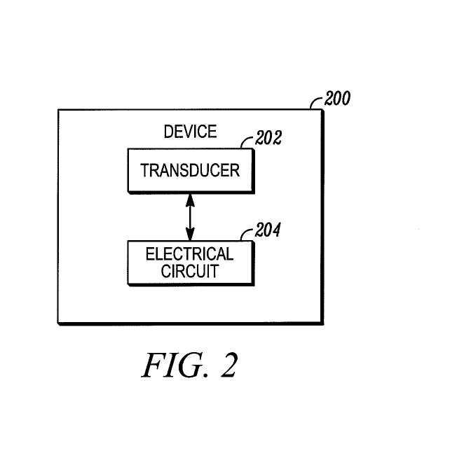

FIG. 2 illustrates the device 200 that can mitigate an unintended-mechanical strain experienced by the device 200, in accordance with at least one embodiment of the present invention, such as the type of device 100 illustrated and discussed in connection with FIG. 1. The device 200 includes a transducer 202 and an electrical-circuit 204. The transducer 202 is integrated with and/or coupled to one or more elements forming at least part of the device 200. The transducer 202 is generally associated with the corresponding element in such a way that when a portion of the element vibrates and/or flexes a corresponding vibration or flexure is translated to the associated transducer. The transducer 202 then converts the flexure of the transducer resulting from a strain-energy applied to the device 200 to electrical-potential energy. The strain-energy can develop in parts of the device 200, that might be subjected to an due to an unintended-mechanical strain, such as an unintended impact. In at least one embodiment, the transducer 202 can be a piezo-electric sensor. This piezo-electric sensor can generate an electrical-voltage in response to the mechanical strain experienced by the corresponding element of the device 200. The magnitude of the electrical-potential energy developed can depend on a magnitude of the flexure due to the unintended-mechanical strain experienced by the device 200. In at least one embodiment, the magnitude of the electrical-potential energy can be directly proportional to the magnitude of the unintended-mechanical strain. Therefore, the magnitude of the electrical-potential energy can be high when the magnitude of the unintended-mechanical strain is high. Examples of a piezo-electric material can include, but are not limited to, lead-zirconate titanate, cadmium sulphide, gallium phosphate, quartz, and tourmaline. Further, the magnitude of the electrical-potential energy can depend on a piezoelectric constant of the transducer 202. The piezoelectric constant is a measure of the ability of the transducer 202 to develop electrical-potential energy in response to the unintended-mechanical strain, and corresponding flexure.

In at least one embodiment of the present invention, the transducer 202 can be surface-mounted on at least one component of the device 200. Examples of the components can include, but are not limited to, the housing structural element of the device 200, a keyboard, a liquid-crystal display (LCD) holder, the device-battery cover of the device 200, and a printed circuit board (PCB) component.

The electrical-potential energy generated by the transducer 202 can then be dissipated via an energy dissipating electrical-circuit 204. In at least one embodiment of the present invention, the electrical-circuit 204 can include a resistor. The resistance of the electrical-circuit 204 provides impedance to the flow of electric current developed due to the electrical-potential energy generated in the associated transducer. The resistor can then dissipate the electrical-potential energy as heat-energy, which in turn allows at least some of the received energy to be more safely dissipated into the surrounding environment, as opposed to the applied energy resulting in further flexure and/or deformation of the associated element. In at least one embodiment, the resistor can be integrated with the transducer 202. The electrical-circuit 204 can also include either an electric battery or an inductor or both. The electric current developed can charge the battery in the electrical-circuit 204. Further, the electrical current can produce a magnetic field in the inductor. This magnetic field is produced in a way that opposes the flow of current through the inductor, therefore providing impedance to the flow of the electrical current. In some embodiments of the present invention, the transducer 202 can be integrated with the electrical-circuit 204.

One skilled in the art will readily appreciate that the device 100 can include additional components that are not separately shown here, at least some of which may similarly be associated with a transducer and corresponding electrical circuit. Since the additional components that include an associated transducer will generally behave in a like manner they do not need to be separately discussed. Still further, any additional components which are not associated with a corresponding transducer are not germane to the operation of the device 100, in the context of the direct beneficial effects of the present invention. However, even components which do not have an associated transducer may still benefit from the present invention, in so far as they may be in energy transferring proximity to a component that includes a transducer. In other words, a particular component may indirectly receive strain energy through another component, which in turn might be mitigated in both components through a transducer coupled to or integrated with one of the components, which is configured to dissipate some of the energy.

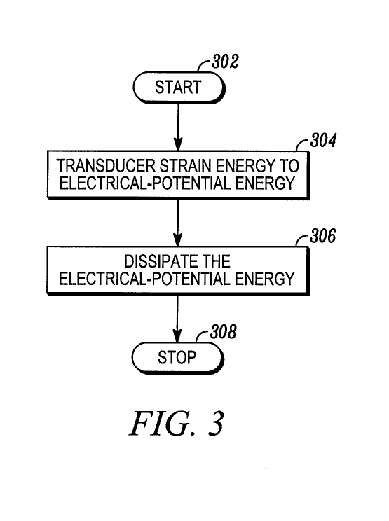

FIG. 3 is a flow diagram illustrating a method for mitigating an unintended-mechanical strain in the device 100, in accordance with at least one embodiment of the present invention. The method for mitigating the unintended-mechanical strain is initiated at step 302. At step 304, the strain-energy is transduced to electrical-potential energy, such as a voltage differential. In at least one embodiment, the transducer 202 can covert the strain-energy to electrical-potential energy. The strain-energy can develop in the device 100 due to the unintended-mechanical strain. A magnitude of the strain-energy can depend on a magnitude of the unintended-mechanical strain. The unintended-mechanical strain can be generated due to an impact force received by the device 100. At step 306, the electrical-potential energy is dissipated via the electrical-circuit 204 of the device. The electrical-circuit 204 can include a resistor, an inductor, a capacitor and an electrical battery. The method is thereafter terminated at step 308.

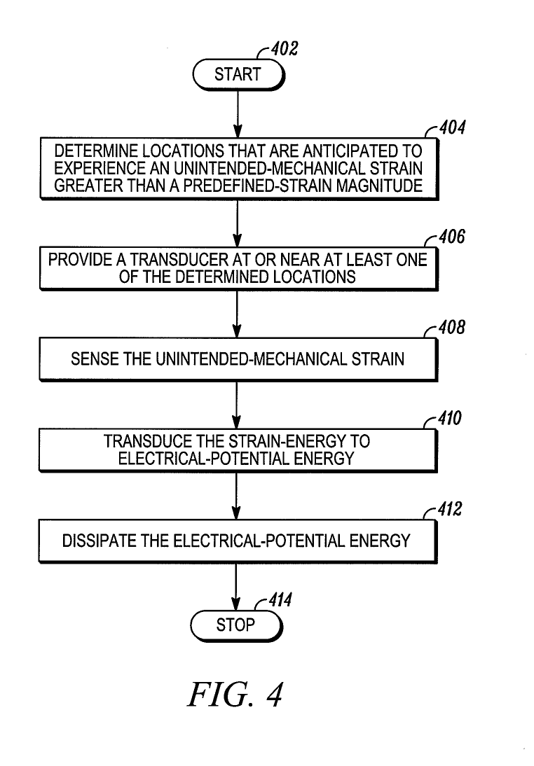

FIG. 4 is a flow diagram illustrating a method for mitigating unintended-mechanical strain in a device, in accordance with at least one embodiment of the present invention. The method explained in conjunction with FIG. 4 can be used in a wireless-communication device. An example of the wireless-communication device can be the device 100 illustrated in FIG. 1. The device 100 can be subjected to an impact force. An example of the device 100 experiencing an impact force can be during a free-fall of the device 100. The method is initiated at step 402. At step 404, one or more locations are determined around the device 100 that are anticipated to experience an unintended-mechanical strain that is greater than the magnitude of the predefined strain. The magnitude of the predefined strain can depend on a maximum strain the device 100 is intended to withstand. This maximum-intended strain can depend on the mechanical strength properties of the materials of which the device 100 is made. Examples of the mechanical-strength properties can include, but are not limited to, the yield strength, the strain at failure, Young's modulus, and the impact toughness. Further, the maximum intended strain can depend on a permissible strain allowed for the material the device 100 is made of. The permissible strain can be based on the level of performance expected from the device 100. For example, a mobile-phone can fall accidentally from a height and strike a floor surface. The mobile-phone gains kinetic energy before hitting the floor surface. A mechanical strain can develop in the mobile-phone on striking the floor surface.

For a better understanding of this example, the value of the predefined-strain magnitude can be taken as 0.005, where strain magnitude corresponds to the ratio of the change in length due to the applied strain divided by the original length. Generally, a predefined-strain magnitude will be selected so as to be less than the overall amount of strain that can typically be withstood without breakage. Different materials and/or components will generally be able to tolerate different amounts of strain. For example, some glass reinforced plastic materials commonly used in a housing for a device can typically withstand a strain magnitude of 10 percent or 0.1, while the glass used in a display tends to be more sensitive to strain being able to generally withstand a strain magnitude of 0.006. Further, one or more locations around the mobile-phone can be identified that are anticipated to experience unintended-mechanical strain of more than 0.005. In this case, it can be assumed that the bottom surface of the housing of the mobile phone will potentially experience the unintended-mechanical strain of more than the predefined-strain magnitude.

At step 406, the transducer 202 is provided at, or near, at least one of the determined locations around the device 100. The application of transducer 202 at, or near, the determined locations does not need to affect the thickness of the device 100, as the transducer can often be integrated into the existing material. Furthermore, the integration of an impact energy dissipating transducer might even allow some otherwise present reinforcing material to be removed. Still further, the cost of the device 100 need not be materially affected. Therefore, the transducer 202 can be provided at those locations where the transducer 202 is most susceptible and/or required to mitigate the consequences of unintended-mechanical strain. Examples of such locations can include, but are not limited to, locations at the bottom surface of the device 100, at the front cover of the housing, at the holder of the LCD, and the battery door of the device 100.

The embodiment can be better understood by considering the example of the mobile-phone when it strikes the floor surface and lands with the bottom surface of the housing touching the floor surface. In this example, the transducer 202 can be provided at the bottom surface of the housing of the mobile-phone. In at least one embodiment of the present invention, the transducer 202 can be integrated with the structure of the device 100. In another embodiment, the transducer 202 can be laminated on a surface of the device 100. For example, a piezo-electric sensor such as quartz can be laminated on the bottom surface of the housing of the mobile-phone. Presumably, any flexure in an element for which a transducer is associated will result in a related flexure in the associated transducer, regardless as to whether the transducer is coupled to or integrated with the element. In turn, any flexure in the associated transducer will produce an electrical-potential energy, which can then be dissipated in an electrical circuit element, such as a resistor, coupled thereto. The dissipation of at least some of the strain-energy will allow for some of the energy that might otherwise result in further flexure of the element to be converted into electrical-potential energy, which can then be redirected and correspondingly dissipated.

At step 408, the unintended-mechanical strain developed in the device 100 is sensed. The magnitude of the unintended-mechanical strain developed can be based on the magnitude of the impact force received by the device 100, which can depend on the relative speed of the device 100 and the surface, and also on the hardness of the surface. Moreover, the magnitude of the impact force can be directly proportional to the relative speed of the device 100 and the surface. For example, the magnitude of the impact force can be low when the relative speed of the device 100 and the surface is low. In the example of the mobile-phone discussed above, the magnitude of the impact force received by the mobile-phone can be 0.36 Newton when the relative speed of the mobile-phone with respect to the floor surface is 5.5 meters per second. The magnitude of the impact force can also depend on the momentum of the device 100 with respect to the surface. Further, the magnitude of the unintended-mechanical strain can depend on the direction and angle of the impact force with respect to a surface of the device 100. For example, the magnitude of the unintended-mechanical strain can be low when the direction of the impact force is parallel to the surface of the device 100. Furthermore, the magnitude of the unintended-mechanical strain can be high when the direction of the impact force is perpendicular to the surface of the device 100. For example, when the mobile-phone falls such that the direction of the impact force is perpendicular to the bottom surface of its housing, the magnitude of the impact force received at the mobile-phone can be 0.32 Newton. This impact force may induce acceleration in the mobile-phone and its components for a very short period of time, typically less that 1 second, often on the order of 1 to 10 milliseconds. The magnitude of this acceleration can depend on the mass of the mobile-phone and its components. Moreover, the magnitude of the unintended-mechanical strain can depend on a material-constant of the material of which the device is made. The material-constant is a measure of the ability of the material of the device to develop mechanical strain in response to the impact force received. In at least one embodiment, the transducer 202 can be adapted to sense the unintended-mechanical strain, for example, through a corresponding flexure.

At step 410, a strain-energy is transduced to electrical-potential energy. The strain-energy is developed in the device 100 due to the unintended-mechanical strain. The magnitude of the strain-energy can depend on a magnitude of the unintended-mechanical strain. In at least one embodiment of the present invention, the transducer 202 can be adapted to transduce the strain-energy to electrical-potential energy. For example, when unintended-mechanical strain is generated in the mobile-phone, quartz can transduce the strain-energy of the unintended-mechanical strain to electrical-potential energy.

At step 412, the electrical-potential energy is dissipated via the electrical-circuit 204 of the device 200. The magnitude of the electrical current flowing in the electrical-circuit 204 can be based on the magnitude of the electrical-potential energy. In at least some instances, the magnitude of the electrical current will be proportional to the magnitude of the electrical-potential energy. Therefore, the magnitude of the electrical current can be low when the magnitude of the electrical-potential energy is low. For example, in the case of the falling mobile-phone, the magnitude of the electrical current can be 0.10 milliampere when the magnitude of the electrical-potential energy is 0.20 Joules.

Further, the magnitude of the electrical current can depend on the magnitude of an electrical resistance of the electrical-circuit 204. For at least one embodiment of the present invention, the resistor can be adapted to provide electrical resistance to the electrical-circuit 204. For at least one embodiment of the present invention, the piezo-electric sensor can be adapted to provide electrical resistance to the electrical-circuit 204. For example, quartz can be adapted to provide the electrical resistance.

In at least one embodiment of the present invention, the electrical-potential energy can be dissipated as heat-energy, sound-energy or light-energy. For example, in the example of the mobile-phone discussed earlier, the electrical-potential energy at the mobile-phone can be dissipated by quartz. In this case, quartz can also be adapted to provide the electrical resistance. Quartz can heat up due to the electric current, thereby dissipating the electrical-potential energy in the form of heat-energy. Further, the electrical-potential energy can be dissipated by starting an alarm when the device 100 receives an impact force. For example, when a person sits on a mobile phone by mistake, an alarm can be triggered. This alarm can dissipate the electrical-potential energy, either in the form of light or in the form of sound. In another example, a Light Emitting Diode (LED) can be provided in the mobile-phone. In this case, the LED can emit light to dissipate the electrical-potential energy. Thereafter, the method is terminated at step 414.

In another embodiment, the present invention can be applied to other types of devices including a laptop device. Laptop devices being generally larger than handheld devices can often experience a larger impact force when it falls from a work surface, such as a desk top, and lands on a floor surface. By the time it hits the floor, the laptop gains kinetic energy due to a velocity developed under the influence of gravitational force. If the weight of the laptop is taken to be 1.5 kg and the relative speed 5 meters per second, the kinetic energy dissipated at the laptop can be about 18.75 Joules. The impact force received by the laptop can be approximately 15 Newton. An unintended-mechanical strain will develop in the laptop due to the impact force received by the laptop. The laptop will have a predefined-strain, which under at least some circumstances can be safely tolerated. In at least some exemplary laptops a predefined permissible strain of 0.18 is possible. However, during the type of fall described above, the bottom and sidewalls of the casing of the laptop depending upon the orientation of the laptop during the impact can be expected to experience an unintended-mechanical strain that might be greater than 0.32. The unintended-mechanical strain should be mitigated at these locations. To do so, a piezo-electric sensor such as gallium phosphate can be provided at the bottom and sidewalls of the casing of the laptop. Further, gallium phosphate can be integrated, pasted or laminated on the internal structure of the casing. Gallium phosphate can sense the unintended-mechanical strain developed in the laptop. The mechanical strain in turn has a corresponding amount of strain-energy that is developed in the laptop due to the impact. The strain-energy developed in the laptop in the current example is 18.75 Joules. This strain-energy can be transduced to electrical-potential energy by gallium phosphate. This electrical-potential energy can then be dissipated by using an electric circuit in the laptop. An electric current is applied to the electric circuit, which in turn dissipates the electrical-potential energy. When the magnitude of the electric-potential energy is 18.75 Joules, an electric current of approximately 5.200 milliampere is possible, which in turn could be coupled to the electric circuit. Gallium phosphate is adapted to provide resistance in the electric circuit. Gallium phosphate heats up due to the resistance of the electric circuit, and this heat is dissipated into the surrounding environment or atmosphere as heat-energy.

Various embodiments of the present invention, as described above, enable the mitigation of unintended-mechanical strain in a device. The present invention significantly increases the robustness of a device. Further, the device can be protected from unintended-mechanical strain that is developed due to an impact force. This results in an improvement in the performance of the various components of the device that can suffer damage because of the unintended-mechanical strain. The present invention can help to make the device more reliable, and thereby reduce the need to additionally strengthen and stiffen various components of the device.

In the foregoing specification, the invention and its benefits and advantages have been described with reference to specific embodiments. However, one with ordinary skill in the art will appreciate that various modifications and changes can be made, without departing from the scope of the present invention, as set forth in the claims. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage or solution to occur or become more pronounced are not to be construed as critical, required or essential features or elements of any or all the claims. The invention is defined solely by the appended claims, including any amendments made during the pendency of this application, and all equivalents of those claims, as issued.

What is claimed is:

1. A device comprising:
a transducer capable of converting strain-energy to electrical-potential energy, wherein the strain-energy is developed in the device due to an unintended-mechanical strain, wherein the unintended-mechanical strain is generated due to an impact force received by the device; and
an electrical-circuit capable of dissipating the electrical-potential energy via the electrical-circuit.

2. The device of claim 1, wherein the device is a wireless-communication device.

3. The device of claim 1, wherein the transducer is a piezo-electric sensor.

4. The device of claim 3, wherein the piezo-electric sensor is selected from a group comprising lead-zirconate titanate, gallium phosphate, quartz, and tourmaline.

5. The device of claim 1, wherein the electrical-circuit comprises at least one of an electric battery, a resistor, and an inductor.

6. The device of claim 1, wherein a magnitude of the electrical-potential energy depends on at least one of a magnitude of the unintended-mechanical strain and an piezoelectric constant of the transducer.

7. The device of claim 1, wherein the transducer is surface-mounted on at least one component of the device.

8. The device of claim 7, wherein the at least one component of the device is selected from a group comprising a housing structural element, a liquid-crystal display (LCD) holder, a device-battery cover, and a printed circuit board component.

9. A method for mitigating an unintended-mechanical strain in a device, the method comprising:
transducing strain-energy to electrical-potential energy, wherein the strain-energy is developed in the device due to the unintended-mechanical strain, and wherein the unintended-mechanical strain is generated due to an impact force received by the device; and
dissipating the electrical-potential energy via an electrical-circuit on the device.

10. The method of claim 9 further comprising sensing the unintended-mechanical strain developed in the device.

11. The method of claim 9, wherein the electrical-potential energy is dissipated as at least one of a heat-energy, a sound-energy, and a light-energy.

12. The method of claim 9, wherein the unintended-mechanical strain depends on at least one of a magnitude of the impact force received by the device, a direction of the impact force with respect to a surface of the device, and a material-constant of a material of the device.

13. The method of claim 9, wherein the electrical-circuit comprises at least one of an electric battery, a resistor, and an inductor.

14. The method of claim 9 further comprising
determining one or more locations around the device, that are anticipated to experience the unintended-mechanical strain greater than a predefined-strain magnitude; and
providing a transducer at, or near, at least one of the determined one or more locations of the device.

15. The method of claim 9, wherein the impact force is due to a free-fall of the device under gravity.
